(19) United States
(12) Patent Application Publication
(10) Pub. No.: US 2009/0087339 A1
(43) Pub. Date: Apr. 2, 2009

(54) METHOD FOR FORMING RUTHENIUM COMPLEX FILM USING Beta-DIKETONE-COORDINATED RUTHENIUM PRECURSOR

(75) Inventor: Hiroshi Shinriki, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/203,405

(22) Filed: Sep. 3, 2008

Related U.S. Application Data
(60) Provisional application No. 60/976,378, filed on Sep. 28, 2007.

(51) Int. Cl. B32B 15/00; C23C 16/00

(52) U.S. Cl. 420/462; 427/250

(57) ABSTRACT

A method for depositing a thin ruthenium (Ru) film on a substrate in a reaction chamber, comprising: step (i) of supplying at least one type of gas of a ruthenium precursor being a β-diketone-coordinated ruthenium complex and causing the gas to be adsorbed to the substrate in the reaction chamber; step (ii) of supplying a reducing gas into the reaction chamber and exciting the reducing gas, or supplying an excited reducing gas into the reaction chamber, in order to activate the ruthenium precursor adsorbed to the substrate; and step (iii) of repeating steps (i) and (ii) to form a thin ruthenium film on the substrate.

### CROSS-REFERENCE TO RELATED APPLICATIONS

This application claims the benefit of U.S. Provisional Application No. 60/976,378, filed Sep. 28, 2007, and the disclosure of which is herein incorporated by reference in its entirety.

### BACKGROUND

1. Field of the Invention

The present invention relates to a method for forming a ruthenium (Ru) film for metal wiring structures that can be used favorably in the creation of fine semiconductor elements in general.

2. Description of the Related Art

Ru film is drawing the attention for its property to improve the adhesion with Cu, when a Ru film is formed at the interface between Cu and barrier metal in a Cu wiring structure which is the main wiring structure used in high-speed logic elements such as MPUs, and thereby significantly enhance the reliability of wiring. Methods are being studied to form a Ru film that provides a Cu diffusion barrier metal on a TaN film or WN film and then form a Cu film on top of the Ru film (one example of such method relating to a combination of Ru and TaN is described in C. C. Yong et al., “Physical, Electrical, and Reliability Characterization of Ru for Cu Interconnects,” IITC 2006, pp. 187-189). To be specific, Cu liners having a laminated structure constituted by Ru/TaN, etc., are being studied.

With Cu liner films constituted by Ru/TaN, etc., which are examined for utilization as Cu wiring liners, the Cu wiring volume becomes relatively smaller as the thickness of the Cu liner film increases, and accordingly the Cu wiring resistance tends to become higher when the film is thicker. For this reason, it is necessary to form as thin a film as possible. In reality, however, a laminated structure constituted by a copper diffusion barrier film and Ru film prevents the formation of continuous film when the Ru film is made thinner, and the barrier film is partially exposed as a result. Consequently, an interface of Cu wiring and barrier film is created and this interface can present problems. On the other hand, making the Ru film thicker as a way to form a continuous film increases the Cu wiring resistance. In other words, it is desirable to form a thin but continuous Ru film. It is also desirable that this Ru film be formed in a reducing atmosphere in order to prevent the aforementioned barrier film from being oxidized when the Ru film is formed on a copper diffusion barrier film such as a TaN film or TaNC film.

According to U.S. Patent Laid-open No. 2006/0177601A, a Ru film can be formed in a reducing atmosphere through a step to supply a Ru material containing a ligand constituted by a cyclopentadienyl group and another step to treat a substrate using NH₃ gas activated by high frequency.

In an embodiment of the present invention, at least one of the problems described below can be solved.

Although TaN and TaCN films are excellent copper diffusion barriers, when a Ru film is formed in an oxidizing atmosphere in the process of forming a Ru/TaCN or Ru/TaN laminated structure, it is possible that TaN or TaCN is oxidized. When Ru is formed by means of NH₃ plasma, on the other hand, TaN or TaCN may be nitrided. Either way, the resistance will increase. This is probably because the very high resistance of the tantalum nitride having a Ta₃N₅ composition causes the nitrogen content to increase as a result of nitriding of TaN/TaCN, thereby resulting in higher resistance. There are also reports that when the preferred orientation of the crystal of Ru film becomes (002), the adhesion with Cu film becomes more favorable (for example, refer to Hoon Kim et al., “Cu Wettability and Diffusion Barrier Property of Ru Thin Film for Cu Metallization,” Journal of The Electrochemical Society, 152 (8) G594-G600 (2005)), which means that controlling the crystalline property of Ru film is very important. According to U.S. Patent Laid-open No. 2006/0177601A, a Ru film can be formed in a reducing atmosphere through a step to supply a Ru material containing a ligand constituted by a cyclopentadienyl group and another step to treat a substrate using NH₃ gas activated by high frequency. However, the Ru film obtained this way tends to have a random crystalline orientation. Accordingly, a method for forming a Ru film having a greater preferred orientation along (002) is desired.

### SUMMARY

In an embodiment, the present invention provides a method for depositing a thin ruthenium (Ru) film on a substrate in a reaction chamber, wherein this method comprises: step (i) to supply at least one type of gas of a ruthenium precursor being a β-diketone-coordinated ruthenium complex and cause the gas to be adsorbed to the substrate in the reaction chamber; step (ii) to supply a reducing gas into the reaction chamber and excite the reducing gas, or supply an excited reducing gas into the reaction chamber, in order to activate the ruthenium precursor adsorbed to the substrate; and step (iii) to repeat steps (i) and (ii) to form a thin ruthenium film on the substrate. “Activate” means, in an embodiment, severing the β-diketone ligand bond with the ruthenium precursor and thereby discharging β-diketone, which in turn means promoting the formation of a purer ruthenium film.

In an embodiment, the ruthenium complex coordinated by β-diketone has the structure shown below:

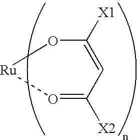

Here, X1 and X2 are hydrocarbons that are independent of each other or for each ligand, where X1 and X2 may form a hydrocarbon ring. Both X1 and X2 are desirably an alkyl group (such as an alkyl group having 1 to 4 carbon atoms), expressed by CR1R2R3 in an embodiment, where R1, R2 and R3 are hydrogen or CmH₂ m+1 (m=1 to 3) (preferably a hydrogen or ethyl group) and independent of one another. Also, n is a value between 1 and 4, or 2 or 3 in an embodiment. Each β-diketone coordinated to ruthenium may be the same or different. In some cases, each group may be further substituted by other group. It is easy to form a nucleus and obtain a desired orientation with ruthenium complexes described above, which is extremely effective in an early step of the film formation process. It is also possible to form a film constituted by such ruthenium complex to reduce the resistivity of the obtained ruthenium film without using ammonia plasma as required in conventional methods.

In an embodiment, the coordination of β-diketone and ruthenium is achieved by conjugation of the second ketone group and C═C double bonds. In other words, β-diketone assumes a conjugated structure upon coordination.

If two β-diketones are coordinated to ruthenium to form a conjugated structure, for example, a structure like the one illustrated below may be obtained:

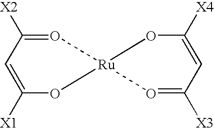

Here, in an embodiment, X1 to X4 are independently —CH₃, —C(CH₃)₃, —CH(CH₃)₂ or —CH₂(CH₃). X1=X4 and X2=X3 may be established, and if X1=X4, then X2≠X3 may be true. X1 may be the same as or different from X2, and X3 may be the same as or different from X4. Also, X1 and X2, or X3 and X4, may together constitute a ring such as 1,3-cyclohexane dione.

There are cases where coordination is achieved without forming a conjugated structure. FIGS. 1(a) and (b) show examples of such case. In both FIGS. 1(a) and (b), the double bonds of two carboxyl groups still remain. However, these are only schematic illustrations and in reality the aforementioned double bonds may be severed and the carboxyl groups may coordinate to ruthenium, or coordination may be achieved by means of conjugated bonding as described above.

An example where three β-diketones are coordinated to ruthenium by means of conjugated bonding is shown below:

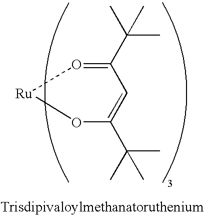

Here, examples of β-diketone (1,3-diketone) include diketone having 5 carbon atoms expressed as follows:

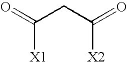

X1 and X2 are the same as the corresponding items in the formula mentioned earlier.

This structure may be 2,4-pentendione, for example, where there may be hydrogen at both ends or each end may be substituted by an alkyl group having around 1 to 3 carbon atoms. Specific examples of β-diketone include acetyl acetone, dipivaloyl methane, diisobutyryl methane and isopivaloyl methane.

One or more types of ruthenium complexes coordinated by β-diketone may be used alone or in combination. Also, such one or more types of β-diketone-coordinated ruthenium complexes may be combined with one or more types of ruthenium complexes coordinated by a ligand other than β-diketone. As for such other ruthenium complexes, those disclosed in U.S. patent application Ser. No. 11/469,828 (U.S. Patent Laid-open No. 2008/0054472) and U.S. patent application Ser. No. 11/557,891 (U.S. Patent Laid-open No. 2008/0124484), both filed by the same applicant for the present application for patent, can be used. The disclosure of each of the above U.S. applications, specifically the disclosure of a ruthenium complex and method for forming a film using such ruthenium complex, is herein incorporated by reference in its entirety. In other words, any part of each of the above U.S. applications may be adopted in any embodiment with respect to the type, forming condition or any other aspect of any reducing gas, oxidizing gas, metal underlayer, laminated structure containing other ruthenium complex layer, copper wiring layer, or the like, disclosed in the present application for patent, without being specifically stated in the present application for patent.

β-diketone-coordinated ruthenium complexes can be synthesized by chemical synthesis manufacturers and therefore can be obtained from chemical synthesis manufacturers.

For purposes of summarizing aspects of the invention and the advantages achieved over the related art, certain objects and advantages of the invention are described in the present disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention.

FIG. 1(a) shows the molecular structure of a Ru precursor used in an embodiment of the present invention.

FIG. 1(b) shows the molecular structure of a Ru precursor used in an embodiment of the present invention.

FIG. 2(a) shows the sequence of a Ru formation process used in an embodiment of the present invention.

FIG. 2(b) shows the sequence of a Ru formation process used in an embodiment of the present invention.

FIG. 3 is a schematic view of a thin film forming apparatus that can be used to implement an embodiment of the present invention.

FIGS. 4(a) to (f) provide a schematic view showing one process based on a process flow of (a)→(b)→(c)→(d)→(e)→(f), used to apply a Ru film forming process conforming to an embodiment of the present invention in a dual damascene Cu wiring process.

FIG. 5 shows X-ray diffraction results of a 5-nm Ru film made of a forming method conforming to an embodiment of the present invention.

FIG. 6 shows crystal analysis results of a conventional Ru film formed on a TaNC film give in an example provided herein.

FIG. 7 shows X-ray diffraction patterns obtained for Ru films (conventional) alone based on the (111) diffraction intensity of a TaNC single-layer film and TaNC (111) diffraction intensity of a conventional Ru/TaNC film.

FIG. 8 shows adhesion evaluation results using a Ru film based on the 4-point bending method in an embodiment of the present invention.

FIG. 9(a) is a TEM cross-section image of a 5-nm Cu-CVD film formed on a Ru film having (002)-preferred orientation.

FIG. 9(b) is a TEM cross-section image of a Cu-CVD film of 5 nm or equivalent formed on a conventional Ru film having a random orientation.

FIG. 10 is a schematic cross-section view of a memory cell of a dynamic random access memory formed by a Ru film forming method conforming to an embodiment of the present invention.

FIGS. 11(a) to (f) provide a schematic view showing one process based on a process flow of (a)→(b)→(c)→(d)→(e)→(f), used to apply a Ru film forming process conforming to an embodiment of the present invention in a dual damascene Cu wiring process.

FIG. 12 shows the structure of an apparatus used to implement a Ru film forming method conforming to an embodiment of the present invention.

### DESCRIPTION OF THE SYMBOLS

1: Chamber
2: Heater stage
3: Exhaust duct
4: Shower plate
5: Gas inlet to lower gas diffusion chamber
6: Gas outlet from lower gas diffusion chamber
7: Lower gas diffusion chamber
8: Gas guide of upper gas diffusion chamber
9: Exhaust valve of upper gas diffusion chamber
10: Center gas mixing pipe
11: Gas diffusion plate
12: Gas outlet from upper gas diffusion chamber
13: Upper lid plate
14: Substrate heating base up/down bellows
15: Substrate
20: Purge valve for material A gas
21: Introduction valve for material A gas
22: Purge gas for center gas mixing pipe
23: Purge gas valve for material B gas
24: Introduction valve for material B gas
25: Main valve on exhaust side
26: Pressure control part
27: Gate valve for molecular pump
28: Gate valve for evacuation
29: Molecular pump
30: Dry pump
31: Introduction valve for bellows purge gas
32: Exhaust valve connecting to diffusion chamber 7
33: RF introduction terminal
34: Radical introduction valve
35: Radical source
36: Oxygen gas introduction valve
37: Transfer gate valve
38: Upper diffusion chamber
101: Lower-layer Cu wiring
102: Inter-layer insulation film
103: Cu barrier insulation film
104: Inter-layer insulation film
105: Cu barrier insulation film
106: Via hole
107: Wiring trench
108: TaNC film
109: Ru film
110: CVD-Cu seed film
111: Cu plating
112: Cu wiring
113: Ru film
114: TaNC film
115: Ru film
116: Cu seed film
117: Cu plating
118: Upper-layer Cu wiring
212: Silicon substrate element
213: Separation range
214: Diffusion layer
216: Conductive contact plug
217: Gate electrode
218: Inter-layer insulation film
219: Conductive wire used as bit wire
221: Insulation film
222: Hole opening provided for formation of capacitor
223: Ru film
224: SrxTiyOz film constituted by high-dielectric-constant Sr, Ti and oxygen
225: Ru film
226: Plate electrode
225: Ru electrode
401: Ru film having (002)-preferred orientation conforming to an embodiment of the present invention
402: Ru film having a random orientation conforming to a conventional method
403: Smooth Cu-CVD film of 5 nm or equivalent, formed on a Ru film having (002)-preferred orientation conforming to an embodiment of the present invention
404: Cu-CVD film whose average film thickness is 5 nm or equivalent, formed on a Ru film having a random orientation conforming to a conventional method
405: TaNC film formed by means of PEALD
301: Cassette loader
302: Atmospheric transfer robot chamber
303: Load lock chamber
304: Vacuum transfer robot chamber
305: Ru film, TaNC film formation module 1
306: Ru film, TaNC film formation module 2
307: Ru film, TaNC film formation module 3
308: Ar carrier gas supply
309: Ru material supply part
310: Ta material supply part
311: Hydrogen gas supply part
312: Ru precursor supply pipe
313: Ta precursor supply pipe
314: Hydrogen gas supply pipe

### DETAILED DESCRIPTION

The present invention will be explained with reference to preferred embodiments and drawings. However, the preferred embodiments and drawings are not intended to limit the present invention.

Favorable embodiments included in the aforementioned embodiments of the present invention are explained below. It should be noted, however, that the present invention is not at all limited to these embodiments.

In an embodiment conforming to one of the aforementioned methods, at least one type of ruthenium complex having a Xa-Ru-Xa or Xa-Ru-Xb structure can be used, where Xa and Xb are different β-diketone ligands and each may have a side chain bonded to at least one of carbon 1 and carbon 5. Take note that each of these side chains may be an alkyl group or non-alkyl group, as long as severance of the bond between the β-diketone group and ruthenium atom is not obstructed.

In an embodiment conforming to one of the aforementioned methods, at least one of Xa and Xb is a β-diketone complex selected from the group that includes an acetyl acetone group, dipivaloyl methane group, diisobutyryl methane group and isopivaloyl methane group.

In an embodiment conforming to one of the aforementioned methods, the excited reducing gas may be generated by applying high frequency to a reducing gas. In an embodiment, the reducing gas is hydrogen, gas containing hydrogen, or gas constituted by hydrogen atoms. In an embodiment, the excited reducing gas is plasma of hydrogen, gas containing hydrogen, or gas constituted by hydrogen atoms. Take note, however, that if nitriding of the underlayer must be avoided, then it is desirable that the excited reducing gas be plasma of hydrogen or mixture gas of hydrogen and inert gas not containing nitrogen atoms.

In an embodiment conforming to one of the aforementioned methods, such method can further include a step, after step (i), to purge the ruthenium precursor gas from the reaction chamber and a step, after step (ii), to purge the excited reducing gas from the reaction chamber.

In an embodiment conforming to one of the aforementioned methods, a thin ruthenium film with a thickness of 0.5 m or more, but not exceeding 2.0 nm, can be formed by repeating steps (i) and (ii).

In an embodiment conforming to one of the aforementioned methods, a thin ruthenium film having a preferred crystalline orientation along Ru (002) can be formed by repeating steps (i) and (ii). This film thickness can also be controlled to a range of 0.5 to 2.0 nm.

In an embodiment, one of the aforementioned methods being used can include a step to add a metal film before steps (i) to (iii) for forming a thin ruthenium film on a metal film. The metal film may be at least one type selected from the group that includes WNC, WN, TaN, RuTaN, Ta, RuTa, TaNC, RuTaNC, TiN, RuTiN, Ti, RuTi, Cu, Al, Co and Ni.

In an embodiment conforming to one of the aforementioned methods, the gas of the ruthenium precursor in step (i) can be used as a first gas, while a further step can be included in step (i) to supply a second gas of a different ruthenium precursor into the reaction chamber simultaneously as the first gas. This different ruthenium precursor may be one having a pentadienyl group coordinated to Ru. Since it is easy to form a nucleus in an initial stage when the Ru precursor having β-diketone is used that constitutes the first gas, a thin ruthenium film can be formed effectively by combining the first gas and different ruthenium precursor.

In other embodiment, one of the aforementioned methods being used can further include, after step (iii) consisting of repetition of steps (i) and (ii) for a specified number of times: step (iv) to supply into the reaction chamber a ruthenium precursor which is the same as or different from the ruthenium precursor supplied in step (i) and cause this ruthenium precursor to be adsorbed to the substrate; step (v) to supply into the reaction chamber an oxidizing gas or excited oxidizing gas so as to activate the different ruthenium precursor adsorbed to the substrate; and step (vi) to repeat steps (iv) and (v) and thereby form a thin ruthenium film or ruthenium oxide film on the substrate. If an oxidizing gas is used, the deposition speed becomes faster and the productivity also improves. The Ru film formed in step (iii) can prevent the oxidization of the metal underlayer.

In other embodiment, one of the aforementioned methods being used can further include, after step (iii) consisting of repetition of steps (i) and (ii) for a specified number of times: step (iv) to supply into the reaction chamber a second gas of a different ruthenium precursor and cause the second gas of the different ruthenium precursor to be adsorbed to the substrate; step (v) to supply an excited reducing gas into the reaction chamber so as to activate the different ruthenium precursor adsorbed to the substrate; and step (vi) to repeat steps (iv) and (v) and thereby form a thin ruthenium film on the substrate. Here, a pentadienyl-group-coordinated form of Ru can be used as the different ruthenium precursor.

In other embodiment, one of the aforementioned methods being used can further include a step, after step (iii), to form a thin ruthenium film or thin ruthenium oxide film on the thin ruthenium film by means of CVD. In this case, oxidization of the underlayer can be prevented by the Ru film formed beforehand, even when CVD is implemented using an oxidizing gas, and thus the underlying metal film will not be oxidized. Also, a ruthenium film can be formed productively using CVD.

In an embodiment conforming to one of the aforementioned methods, a step may be included, after step (iii) or (vi) or after step (iii), to form a copper film on the thin ruthenium film formed by means of CVD. This copper film may be formed based on CVD or ALD or by supplying the gas of a copper precursor to the substrate.

In other embodiment, one of the aforementioned methods being used can further include a step, after step (iii), to form a copper film on the thin ruthenium film having (002)-preferred crystalline orientation. This copper film may be formed based on CVD or ALD or by supplying the gas of a copper precursor to the substrate. Also, the thickness of the film formed in step (iii) is preferably controlled to a range of 2 to 0.5 μm, and also the film preferably has (002)-preferred orientation.

A thin ruthenium film can be formed using a ruthenium complex containing β-diketone. The substrate may have a metal film, and a thin ruthenium film may be formed on the metal film. For this metal film, at least one type can be selected from the group that includes WNC, WN, TaN, RuTaN, Ta, RuTa, TaNC, RuTaNC, TiN, TuTiNi, Ti, RuTi, Cu, Al, Co and Ni. Such metal wiring structure containing ruthenium can further have a copper film on the thin ruthenium film.

The aforementioned metal wiring structure containing ruthenium can also have a thin ruthenium film with a thickness of 0.5 to 2 μm and preferred crystalline orientation along Ru (002), and a copper film can also be provided on this thin ruthenium film.

In an embodiment, the metal film is made of a metal containing Cu, Al or Co, or metal containing Ni, while the thin ruthenium film formation structure may also have a thin ruthenium film with a thickness of 0.5 to 2 nm and preferred crystalline orientation along Ru (002), and furthermore it can be provided as a metal wiring structure containing a ruthenium film characterized in that a metal film made of any metal selected from the group that includes WNC, WN, TaN, RuTaN, Ta, RuTa, TaNC, RuTaNC, TiN, RuTiN, Ti and RuTi is formed on this thin ruthenium film to prevent diffusion of copper. In addition, a copper film can be formed after forming a thin ruthenium film on this metal film for blocking copper diffusion. The purpose here is to form at each of the interfaces with copper films for upper/lower wirings a ruthenium film conforming to an embodiment of the present invention, and then form between these ruthenium films a copper diffusion blocking film made of any metal selected from the group that includes WNC, WN, TaN, RuTaN, Ta, RuTa, TaNC, RuTaNC, TiN, RuTiN, Ti and RuTi, in order to form a favorable interface between ruthenium and copper and thereby enhance the reliability of wiring.

In an embodiment conforming to one of the aforementioned methods, the thickness of the diffusion blocking film formed as a lower layer of the Ru film should be 1 to 10 nm, or preferably be 1 to 3 nm. If a Ru-containing metal film (such as Ru—Ta alloy film or Ru-—Ti alloy film) is used as this lower layer, adhesion with the Ru film can be increased further. A Ru-containing metal film can be implemented based on, for example, the methods disclosed in U.S. patent application Ser. No. 12/129,345 (filed on May 29, 2008) and U.S. patent application Ser. No. 11/955,275 (filed on Dec. 12, 2007), both filed by the same applicant for the present application for patent and the disclosure of each of which is herein incorporated by reference in its entirety for Ru alloy film formation.

The foregoing explained the specific purposes and advantages of embodiments of the present invention in order to summarize the superior advantages offered by these embodiments of the present invention as well as related technologies achieved therein. Each embodiment of the present invention represents a method for forming a ruthenium film, as well as a wiring structure using a ruthenium film formed by such method conforming to an embodiment of the present invention, together with the advantages offered by such ruthenium film and wiring structure. By using as a structure a ruthenium film formed by such method conforming to an embodiment of the present invention, a highly reliable wiring structure can be obtained. In this sense, the ruthenium forming method conforming to an embodiment of the present invention provides an effective invention, not only in respect of the forming method itself, but also in respect of the thin ruthenium film structure and metal wiring structure formed by such method.

Yet other embodiments, characteristics and advantages of the present invention should be revealed through the detailed explanation of favorable embodiments given below.

The aforementioned characteristics of some embodiments of the present invention are explained below by referring to drawings illustrating favorable embodiments.

In the present disclosure where conditions and/or structures are not specified, the skilled artisan in the art can readily provide such conditions and/or structures, in view of the present disclosure, as a matter of routine experimentation.

An embodiment of the present invention is characterized in that it provides a Ru film forming method including a step to supply to a substrate a ruthenium precursor having a Xa-Ru-Xb or Xa-Ru-Xa structure and where Xa and Xb are ligands constituted by β-diketone, and another step to use a reducing gas excited by high frequency to treat the substrate. This embodiment is also characterized in that a Ru film formed by the aforementioned forming method is used.

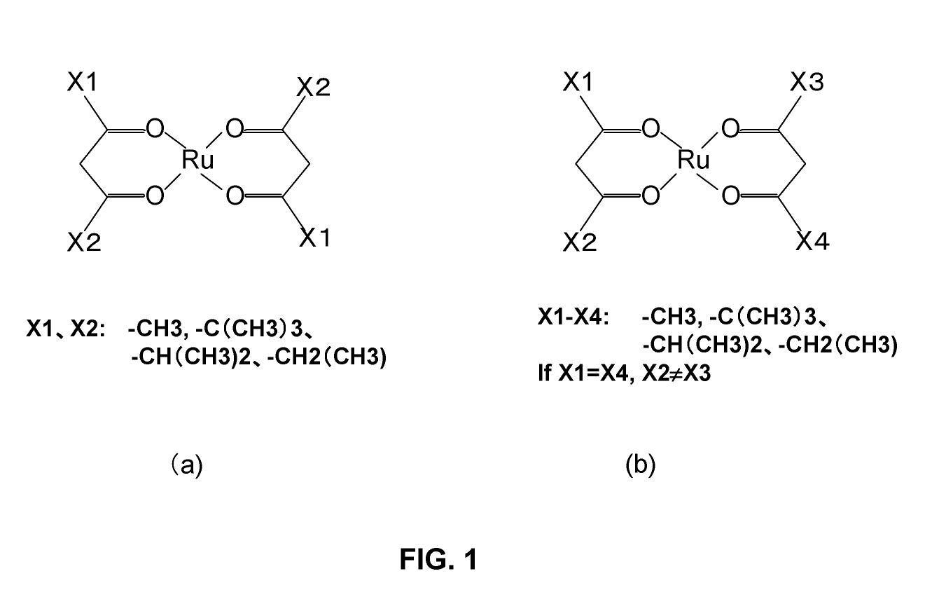

In an embodiment, the ruthenium precursor having a Xa-Ru-Xb or Xa-Ru-Xa structure and where Xa and Xb are ligands constituted by β-diketone may have an acetyl acetone group, dipivaloyl methane group, diisobutyryl methane group or isopivaloyl methane group as a ligand, or it can also have a ligand having a side chain constituted by at least one carbon in the carbon positions at both ends of β-diketone (carbon positions 1 and 5 in the case of 2,4-pentenedione). The molecular structures shown in FIG. 1 illustrate examples of a molecule used in the present invention.

FIGS. 1(a) and (b) show ruthenium precursors having a Xa-Ru-Xa structure and Xa-Ru-Xb structure, respectively. In FIG. 1(a), a Ru precursor having a Xa-Ru-Xa structure is shown. Although this is an example of β-diketone ligand, β-diketone of any type other than the one shown here is also expected to provide similar effects. FIG. 1(b) shows a ruthenium precursor having a Xa-Ru-Xb structure. Here, Xa and Xb are different β-diketone ligands. Again, β-diketone having any side chain not shown here is included in the scope of a Ru precursor used in an embodiment of the present invention and expected to provide similar effects.

Under U.S. Patent Laid-open No. 2006/0177601A1, structures are limited to those having a cyclopentadienyl group and use of other Ru compounds is prohibited. This is because the cyclopentadienyl group is extremely stable chemically and therefore easy to handle. However, severing and removing cyclopentadienyl groups requires ammonia plasma, and this is understood, by the inventor of the present invention, as a key point of the aforementioned invention. On the other hand, a problem exists where the TaN film used as a Cu barrier film will be nitrided if ammonia plasma is used, and this will increase the resistance, as described as the problems to be solved by the present invention. Accordingly, after examining Ru precursors the inventor found that in many cases ligands constituted by β-diketone could be removed from Ru precursors containing β-diketone by using hydrogen plasma, and that the resistivity of ruthenium film could therefore be lowered without using ammonia plasma. It was also revealed that a Ru film formed by this method could be easily oriented to (002) on a metal film. The (002) orientation represents an extremely advantageous orientation to have when a Cu film is to be formed on this Ru film. Accordingly, the method proposed in each embodiment of the present invention presents an extremely advantageous method and innovative technology to achieve a desirable crystalline orientation without having to expose the underlying metal film to nitrogen plasma, which was not possible under the conventional Ru-ALD process.

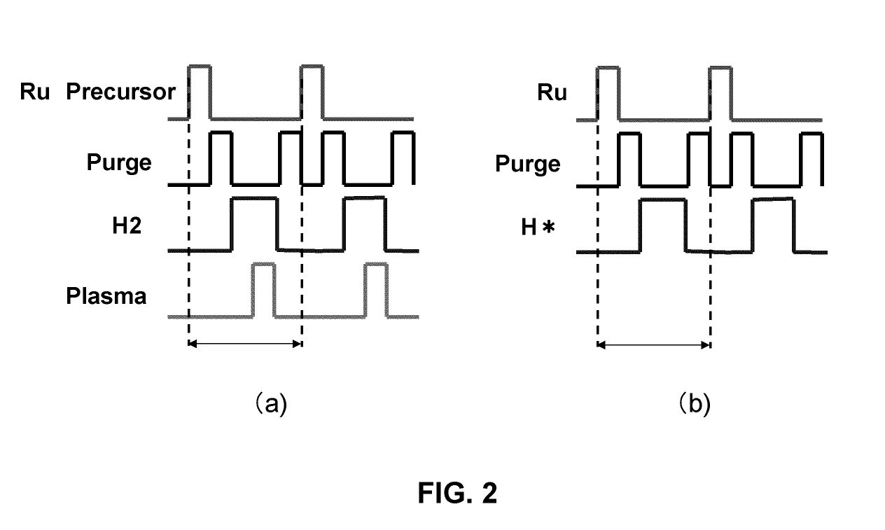

FIGS. 2(a) and (b) show basic processes in embodiments. Take note, however, that the embodiments explained below are not intended to limit the present invention in any way.

In FIG. 2(a), a Ru material gas is supplied onto the substrate first. At this time, the Ru material is heated to a temperature range of approx. 80 to 120° C. (including 90° C., 100° C., 110° C. and any other temperature between the foregoing numbers), and the generated vapor of Ru material is introduced into the reaction apparatus by means of an inert gas (such as Ar). The flow rate of this inert gas is adjusted in a range of approx. 100 to 700 sccm (including 200 sccm, 300 sccm, 400 sccm, 500 sccm, 600 sccm and any other flow rate between the foregoing numbers, but preferably between 300 and 500 sccm). To achieve an optimal vapor pressure of Ru material, the vapor pressure is desirably adjusted to a range of approx. 0.05 to 1 torr (including 0.05 torr, 0.3 torr, 0.6 torr and any other pressure between the foregoing numbers). In this embodiment, the flow rate of evaporated Ru refers to the flow rate of a carrier gas (inert gas) containing Ru, where this carrier gas is used to transport the vapor of Ru material that has been generated by evaporating the material at the aforementioned vapor pressure. Also, the supply pipe may be heated, desirably to 150° C. or other temperature equal to or above 120° C., in order to prevent the evaporated material from liquefying. The ALD process is a self-reducing process, which means that on a substrate where the ALD film has been adjusted to an optimal temperature setting, a Ru precursor supplied under the aforementioned conditions can be adsorbed to the substrate.

Next, the supply of Ru material is stopped and the aforementioned gas is purged (using an inert gas supplied at a flow rate of 1,000 to 3,000 sccm) to discharge the remaining Ru material gas from the reaction chamber. Thereafter, hydrogen gas is introduced and when the process pressure stabilizes, 200 to 1,000 W of high-frequency output (including 300 W, 500 W, 700 W and any other output between the foregoing numbers) based on a high frequency of 13.56 kHz is used to apply high frequency and thereby excite hydrogen (H₂) gas supplied as a reducing gas at a flow rate in a range of 200 to 700 sccm (preferably 300 to 500 sccm), in order to activate the Ru precursor adsorbed to the substrate surface and sever the bond between the Ru element and β-diketone, and also discharge the resulting reaction products from the reaction chamber. Next, introduction of high frequency and that of hydrogen gas, used as reducing gas, are stopped and an inert gas is used to purge the reaction chamber. These steps can be repeated to grow the Ru film.

In FIG. 2(b), a Ru material gas is supplied onto the substrate first. At this time, the Ru material is heated to a temperature range of approx. 80 to 120° C. (including 90° C., 100° C., 110° C. and any other temperature between the foregoing numbers), and the generated vapor of Ru material is introduced into the reaction apparatus by means of an inert gas (such as Ar). The flow rate of this inert gas is adjusted in a range of approx. 100 to 700 sccm (including 200 sccm, 300 sccm, 400 sccm, 500 sccm, 600 sccm and any other flow rate between the foregoing numbers, but preferably between 300 and 500 sccm). To achieve an optimal vapor pressure of Ru material, the vapor pressure is desirably adjusted to a range of approx. 0.05 to 1 torr (including 0.05 torr, 0.3 torr, 0.6 torr and any other pressure between the foregoing numbers). In this embodiment, the flow rate of evaporated Ru refers to the flow rate of a carrier gas (inert gas) containing Ru, where this carrier gas is used to transport the vapor of Ru material that has been generated by evaporating the material at the aforementioned vapor pressure. Also, the supply pipe may be heated, desirably to 150° C. or other temperature equal to or above 120° C., in order to prevent the evaporated material from liquefying. The ALD process is a self-reducing process, which means that on a substrate where the ALD film has been adjusted to an optimal temperature setting, a Ru precursor supplied under the aforementioned conditions can be adsorbed to the substrate.

Next, in an embodiment the aforementioned gas is purged (using an inert gas supplied at a flow rate of 1,000 to 3,000 sccm) to discharge the remaining Ru material gas from the reaction chamber. Thereafter, hydrogen gas that has been excited by microwave beforehand is introduced into the reaction chamber. The Ru precursor adsorbed to the substrate surface is activated by this so-called hydrogen radicals, and as a result the bond of β-diketone with ruthenium is dissociated and β-diketone is discharged from the reaction chamber. H₂ gas can be supplied at a flow rate in a range of 200 to 700 sccm (preferably 300 to 500 sccm). As for the inert gas, Ar can be supplied at a flow rate in a preferable range of 300 to 2,000 sccm (or more preferable range of 500 to 1,200 sccm). The pressure condition can be adjusted to an optimal level between 1 and 3 torr. In an embodiment, the reducing gas is a gas containing hydrogen, and using H₂, or mixture gas of Ar and H₂ or He and H₂, should not present problems. The mixing ratio of H₂ and N₂ is in a range of 0.01 to 1000 in an embodiment, or preferably in a range of 0.1 to 100. The mixing ratio of H₂ and Ar or H₂ and He is in a range of 0.01 to 10 in an embodiment, or preferably in a range of 0.1 to 10.

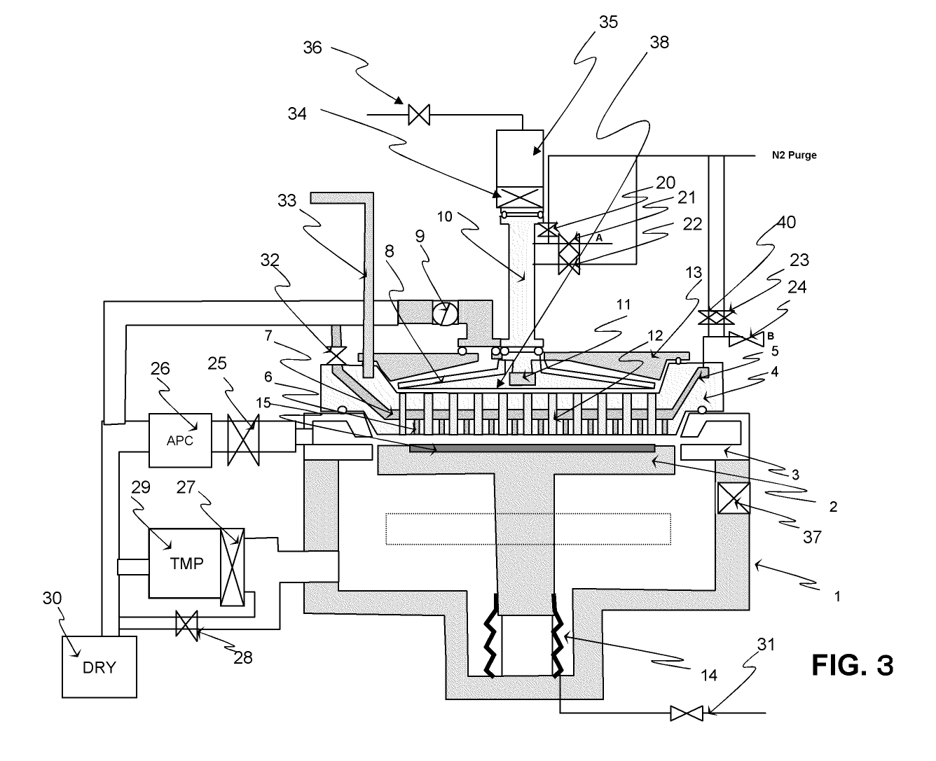

FIG. 3 shows an example of a thin film forming apparatus that can be used to implement an embodiment of the present invention. The basic embodiment of the present invention illustrated in FIG. 2 can be implemented using the apparatus illustrated in FIG. 3. The structure of this apparatus is explained below. This apparatus has a substrate heating base 2 installed in a chamber 1, and a substrate 15 that has been introduced by substrate heating base up/down bellows 14 through a substrate carry-in gate valve 37 is placed on the substrate heating base, after which the substrate heating base rises and moves to a specified position. Furthermore, this apparatus has an exhaust duct 3 made of ceramics and installed on the chamber 1. This exhaust duct also functions as an insulator and implements isotropic exhaust. This exhaust duct 3 is connected to a main valve 25 and a pressure control part 26, and has a function to control the process pressure. Installed above the exhaust duct 3 is a showerhead plate 4 for supplying the process gas uniformly onto the substrate 15. This showerhead plate has two types of gas outlets, including a gas outlet 6 from a lower gas diffusion chamber 7 and a gas outlet 12 from an upper gas diffusion chamber 38. Here, a gate valve for evacuation 28 is provided to facilitate exhaust from the upper gas discharge chamber 38 and also from the bottom of the chamber 1, with the valve connected to a dry pump 30.

In addition, the upper diffusion chamber 38 and lower diffusion chamber 7, both installed at the shower plate 4, have exhaust valves 9, 32 for purging the gas introduced into the diffusion chambers, and it is possible to introduce a purge gas from purge gas introduction valves 20, 40. These functions are provided for the purpose of quickly introducing a purge gas and thus exhausting a reaction gas after the reaction gas has been introduced into the showerhead through valves 21, 23.

How the processes shown in FIGS. 2(a) and (b) can be implemented using the apparatus illustrated in FIG. 3 is explained. In FIG. 2(a), the Ru precursor is supplied from the valve 21, where the Ru precursor travels through the upper diffusion chamber 38 and gas outlet from upper diffusion chamber 12 to be finally supplied onto the substrate 15. After the Ru precursor has been supplied for a specified time, the valve 21 is closed and at the same time the valve 9 is opened, and then nitrogen or argon gas is introduced as a purge gas from the valve 20 to exhaust the material gas constituting the Ru precursor. Thereafter, the valve 20 is closed and the valve 9 is also closed. Next, hydrogen gas is introduced from a valve 24, where this gas travels through the lower diffusion chamber 7 and gas outlet from lower diffusion chamber 6 to be finally supplied onto the substrate 15. Thereafter, high frequency is introduced to the shower plate 4 from numeral 33 to generate hydrogen plasma between the shower plate 4 and grounded substrate heating base 2, thereby activating the Ru precursor adsorbed to the substrate and also sever the bond with the coordinated β-diketone and thereby help discharge β-diketone. Hydrogen plasma treatment is performed for a specified time, after which the application of high frequency is stopped along with the supply of hydrogen gas. At this time, a purge gas can also be supplied from the valve 40. A Ru film can be formed by repeating this sequence.

The process shown in FIG. 2(b) can also be implemented using the apparatus illustrated in FIG. 3. In this case, a Ru film can be formed in the same manner by using a hydrogen radical generation process instead of the hydrogen plasma generation process shown in FIG. 2(a).

This process of introducing hydrogen radicals supplies hydrogen gas from a valve 36, and at the same time a valve 34 is opened and a radical source 35 is started roughly simultaneously. The radical source is designed so that microwave can be introduced, and the introduced hydrogen turns into hydrogen radicals. These hydrogen radicals are supplied onto the substrate 15 through the upper diffusion chamber 38 and gas outlet from upper diffusion chamber 12. After hydrogen radicals have been introduced for a specified time, the radical source 35 is stopped and the gas valves 36, 34 are closed. By replacing the hydrogen plasma process in FIG. 2(a) with this process, it becomes possible to implement a process using hydrogen radicals. Since hydrogen radicals have a relatively long life, they can reach the bottom of holes and trenches not reachable by hydrogen plasma. These holes and trenches are provided in the fine patterns formed on the substrate 15. In other words, hydrogen radicals are effective in forming a Ru film in a manner maintaining good coverage all the way down to the bottom of holes and trenches.

Specific examples are explained using FIGS. 1 to 3 explained above. It should be noted, however, that these examples are not intended to limit the present invention in any way. Also note that numerical values provided in specific examples may be modified over a range of ±50%, for example, and such modified ranges also constitute a part of the present invention.

### EXAMPLE 1

Application of a Ru film to semiconductor copper wiring using the process sequence shown in FIG. 2(a) is explained by using the schematic cross-section structure view in FIG. 3.

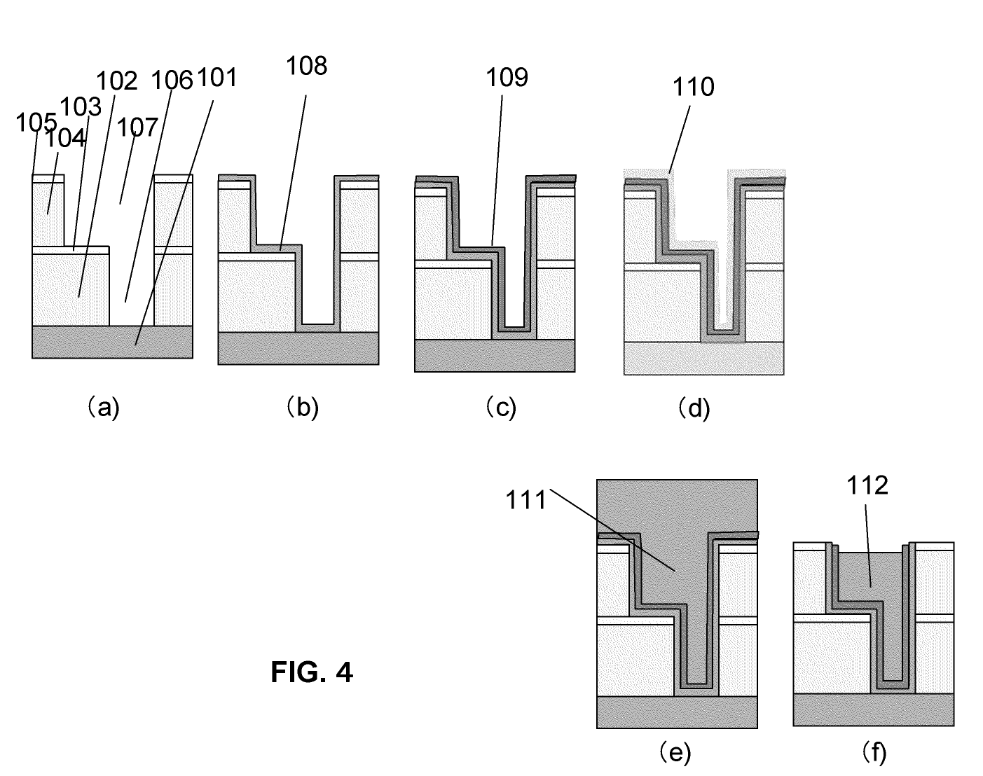

FIGS. 4(a) to (f) show a process for forming a Cu wiring by forming a Cu barrier film via dual damascene wiring and then forming a Cu seed layer, followed by Cu plating and Cu CMP. In FIG. 4(a), a via hole 106 is formed in an inter-layer insulation film 102 and a Cu barrier insulation film 103, and also a wiring trench 107 is formed in an inter-layer insulation film 104 and a Cu barrier insulation film 105, where all of the films are formed on a Cu lower-layer wiring 101. These via hole 106 and wiring trench 107 together constitute a Cu embedding range for dual damascene. In FIG. 4(b), a TaNxCy film 108 is formed over this range for 50 cycles, or approx. 3 nm, using the atomic layer deposition method using TIMATA (Tertiaryamylimidotris(dimethylamido)tantalum) material and hydrogen plasma. This forming method uses a sequence similar to the Ru forming sequence shown in FIG. 2(a). The substrate heating temperature is set to 280° C., and TAIMATA is vaporized at 80° C., and argon carrier gas is supplied at 300 sccm for 0.5 second. Purge is performed, and then hydrogen gas is supplied at 300 sccm, after which high frequency of 13.56 MHz is applied to perform hydrogen plasma treatment. Thereafter, purge is performed in a similar manner. By repeating this cycle 60 times, the thickness of TaNxCy film 108 can be increased to approx. 3 nm. In FIG. 4(c), approx. 1 nm of Ru film 109 is formed after 25 cycles using the Ru forming method conforming to an embodiment of the present invention. The sequence in FIG. 2(a) is used to supply a Ru material constituting a Ru precursor. As for the Ru material, a Ru precursor coordinated by two types of β-diketone, one whose X1 and X2 in FIG. 1(b) are 3H₃ and the other whose X3 and X4 are expressed by 3(CH₃), is supplied for 1 second and then the Ru material is purged in a manner similar to the purge of TAIMATA material, after which hydrogen gas is supplied and high-frequency plasma is applied for approx. 2 seconds. By repeating this cycle around 25 to 100 times, the Ru film thickness can be grown to approx. 1 to 2 nm. Material supply is adjusted within a range of 80 to 150° C. according to the required amount of material to be supplied.

TABLE 2

| | | Flow rate | Temperature | Pressure | Time |
|---|---|---|---|---|---|
| Step | Gas | (Sccm) | (° C.) | (Pa) | (sec) |
| Ru | Precursor | 300 | 280 | 300 | 1 |
| introduction | | | | | |
| Purge | Ar | 2000 | 280 | — | 1 |
| Hydrogen | H2/Ar | 300/2400 | 280 | 250 | 3 |
| plasma | | | | | |
| Purge | Ar | 2000 | 280 | — | 1 |

Table 2 summarizes optimal conditions for this process. Formation of a Ru film using the apparatus illustrated in FIG. 3 is explained. The Ru precursor is controlled to an optimal vaporization temperature range of 80 to 150° C., or more preferable range of 100 to 120° C. Argon carrier gas is supplied at 300 sccm for 1 second from the valve 21. Next, the valve 21 is closed and a valve 22 is opened to introduce nitrogen gas or argon gas at a large flow rate, and the valve 9 is also opened roughly simultaneously to purge and exhaust the Ru material by means of an inert gas. Thereafter, the valves 22, 9 are closed and the valve 34 is opened. Mixture gas of hydrogen gas and argon gas is introduced from the valve 36. Once the pressure stabilizes at 250 Pa, high frequency is applied from the RF introduction terminal 33 to generate plasma. The high-frequency power supply uses 13.56 MHz and is adjusted using a matching box. In FIG. 3, the high-frequency power supply and matching box, which are connected to the RF introduction terminal 33, are not illustrated. Plasma is generated between the grounded substrate heating base 2 and showerhead 4, and after plasma has been supplied for approx. 3 seconds, high-frequency application is stopped and the valves 36, 34 are closed. Thereafter, evacuation is performed for approx. 1 second to complete one cycle. This cycle is set as desired in accordance with the target film thickness, to form a Ru film. Normally 0.2 to 0.4 angstrom of Ru film is formed in one cycle, which means that the process cycle needs to be repeated 100 to 500 times in order to form 5 to 10 nm of Ru.

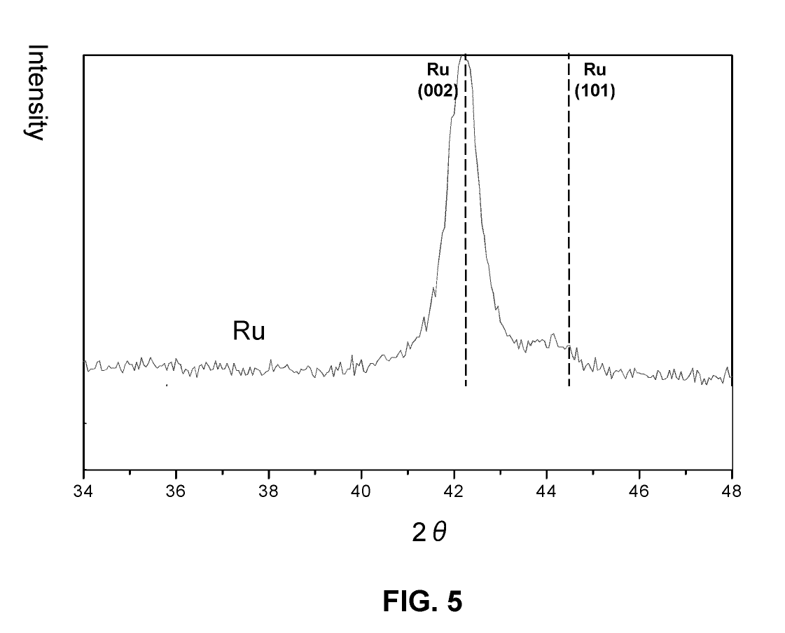

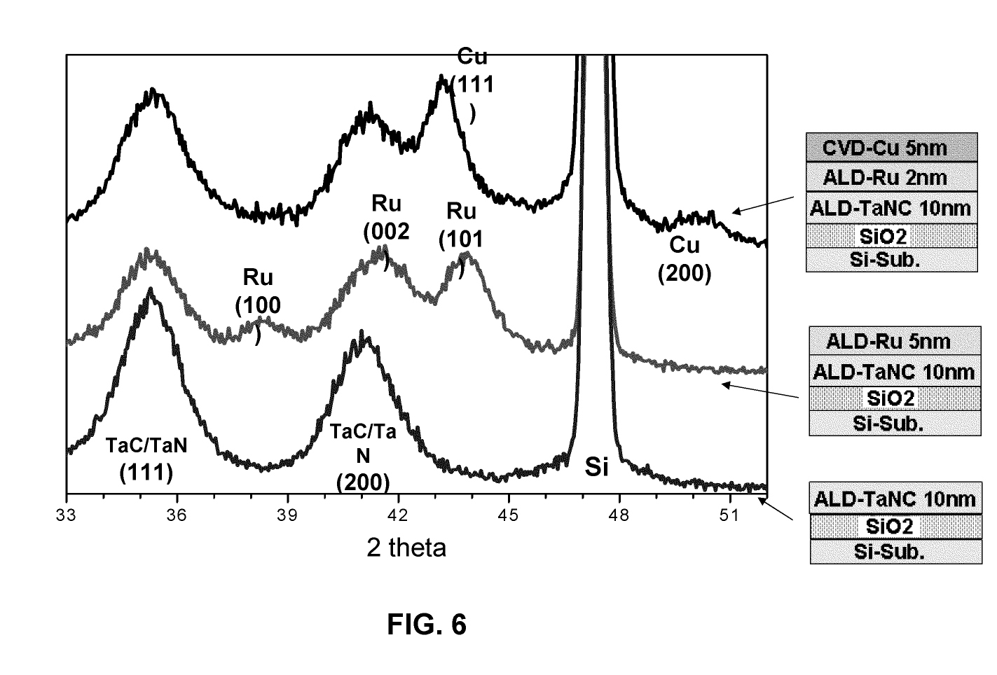

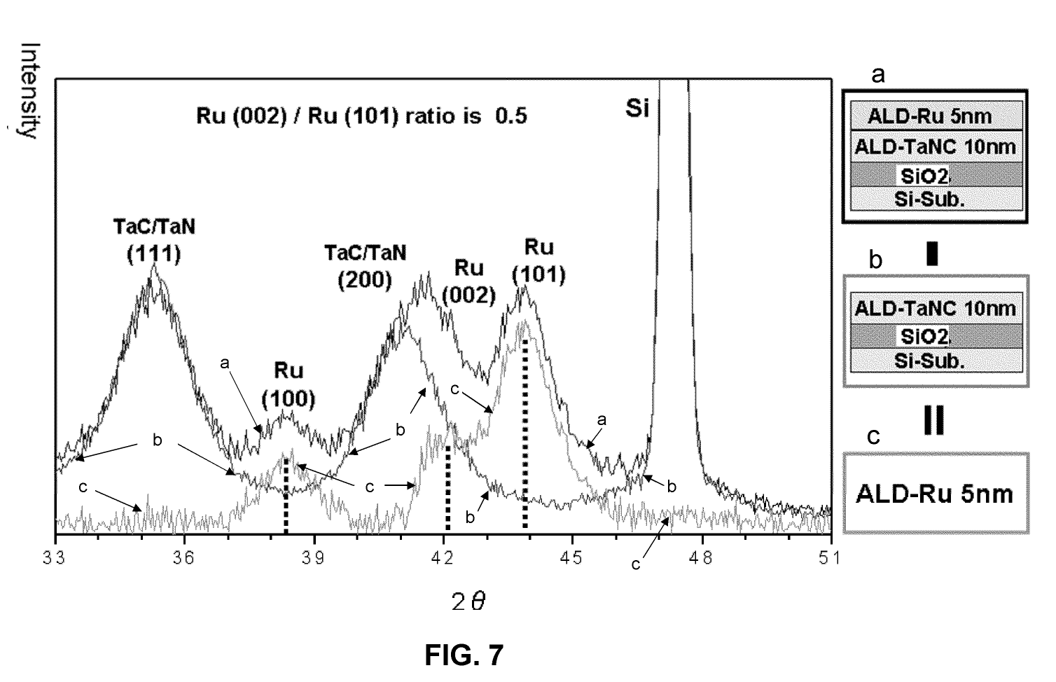

In FIG. 4(d), a 10-nm Cu film 110 is formed by the CVD method, and then Cu 111 is formed by plating. A Cu-CVD film uses Cu(Hfac)2tmvs, and formed on a Ru film conforming to this embodiment using any known Cu-CVD technology. In FIG. 4(e), the surface is polished by Cu-CMP to form a Cu wiring 112. FIG. 5 shows the crystalline property of 5-nm Ru film. As shown, the formed Ru film 109 has (002)-preferred orientation. On the other hand, a Ru film was formed on a TaNC film explained in this example in a similar manner using a method comprising a step to supply a Ru material containing a ligand constituted by a cyclopentadienyl group, as well as a step to use NH₃ gas activated by high frequency, according to U.S. Patent Laid-open No. 2006/0177601A, and crystalline diffraction data of the resulting Ru film was obtained. This data is shown in FIG. 6. This figure shows x-ray profiles of a underlying TaNC film, a laminated film constituted by Ru (conventional)/TaNC films, and a Cu/Ru/TaNC laminated film. FIG. 7 shows X-ray diffraction patterns of Ru films alone, obtained based on the (111) diffraction intensity of a TaNC single-layer film and TaNV (111) diffraction intensity of a Ru/TaNC film. Based on the profile of the conventional Ru film, the intensity ratio of Ru (002) and Ru (101) is 0.5. Meanwhile, the intensity ratio of Ru (002) and Ru (101) in the polycrystalline Ru film shown in Table 1 is also approx. 0.5. Accordingly, the conventional film can be said to have a random crystalline orientation. On the other hand, the intensity ratio of Ru (002) and Ru (101) in the Ru film conforming to an embodiment of the present invention, based on X-ray diffraction, is 5 to 10, suggesting that this Ru film has a preferred orientation along Ru (002) of approx. 10 times or greater compared to the normal Ru of random crystalline orientation. Accordingly, by using a method conforming to an embodiment of the present invention, a favorable crystal matching with Cu can be achieved and a Ru film having (002)-preferred orientation, and therefore providing a possibility for adhesion improvement, can be formed on a TaNC film.

TABLE 1

| 2⊖ | Intensity | h k l |
|---|---|---|
| 38.783 | 60 | 1 0 0 |
| 42.401 | 50 | 0 0 2 |
| 44.369 | 100 | 1 0 1 |
| 58.355 | 50 | 1 0 2 |
| 69.581 | 70 | 1 1 0 |
| 78.304 | 80 | 1 0 3 |
| 82.350 | 20 | 2 0 0 |
| 84.105 | 80 | 1 1 2 |
| 85.948 | 80 | 2 0 1 |
| 92.090 | 20 | 0 0 4 |

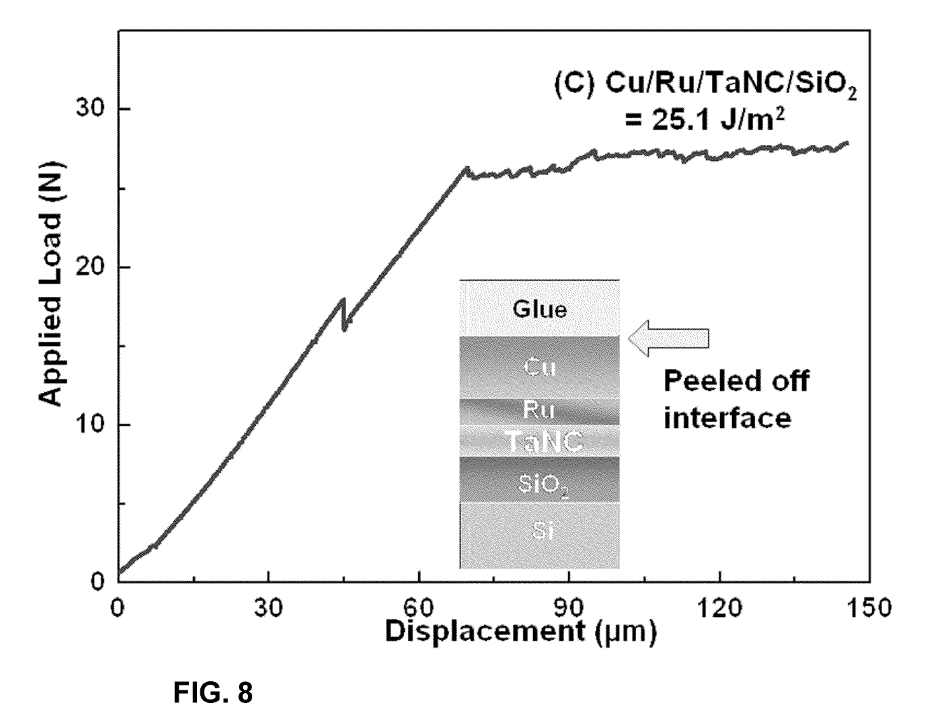

FIG. 8 shows the adhesion evaluation results based on the 4-point bending method. This shows that, by using a structure created according to the method explained in this example, adhesion of 25 J/m² or more could be achieved. This value indicates the adhesion force generated when the Cu and epoxy resin separate, and it is therefore suggested that the aforementioned adhesion force or greater is present at the interface between the Ru film and Cu film in an embodiment of the present invention. Note, however, that the Cu film is formed as a more continuous film on a Ru film having (002)-orientation, and therefore those skilled in the art can easily conceive that greater adhesion can be achieved with a Ru film having (002)-preferred orientation obtained according to this embodiment, than with a traditional Ru film having a random orientation.

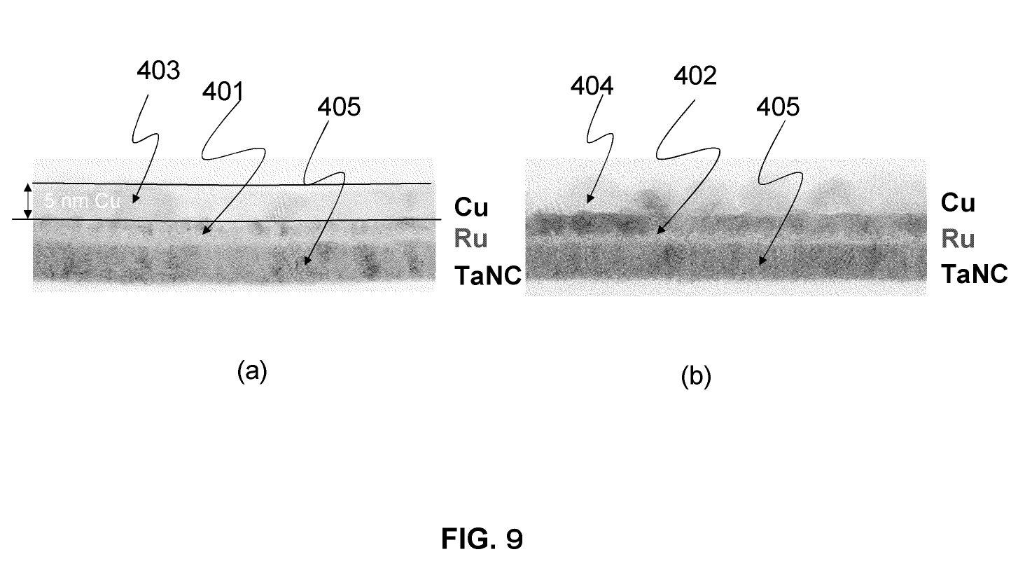

FIG. 9 shows Cu-CVD films formed on two different Ru films, one formed by the method conforming to an embodiment of the present invention on a TaNC film 405 formed by means of TAIMATA hydrogen plasma, and the other formed by the conventional atomic layer deposition method using Ru(EtCp)₂ and NH₃ plasma. FIG. 9(a) shows the result of forming a 5-nm Cu film 403 on a Ru film 401 that has (002)-preferred orientation according to an embodiment of the present invention, while FIG. 9(b) shows the result of forming a Cu-CVD film having a thickness of 5 nm or equivalent on a Ru film 402 having a random orientation. The Cu-CVD film 404 on the Ru film 402 having a random orientation has roughly the same average film thickness as the Cu-CVD film 403, but the former has poorer morphology than the latter. From the TEM cross-section images shown in FIG. 9, it is clear that an extremely smooth 5-nm Cu film can be formed on the Ru film 401 having (002)-preferred orientation as formed according to a method conforming to an embodiment of the present invention. This makes it possible to use this structure to easily form a Cu seed film of 5 nm or less.

As explained above, a Cu wiring offering extremely favorable adhesion and high reliability owing to a smooth Cu seed layer, even after plating, can be formed by using a Ru film conforming to an embodiment of the present invention, and a Cu/Ru/TaNC structure containing such Ru film. Also, use of Ru conforming to an embodiment of the present invention can enhance the reliability of Cu wiring dramatically.

### EXAMPLE 2

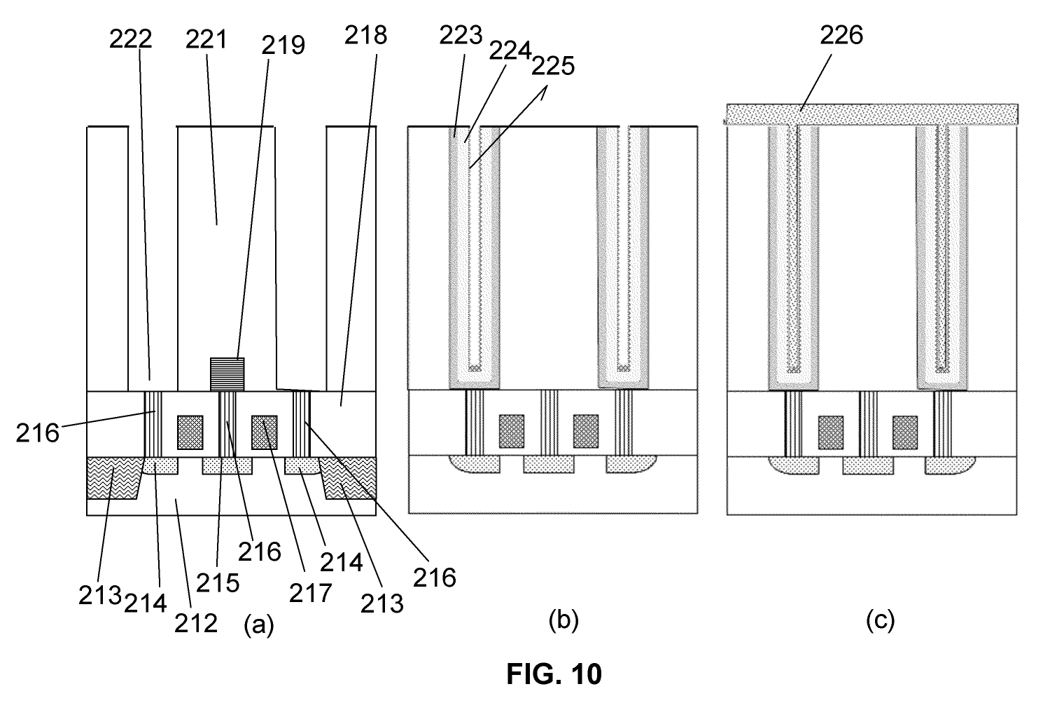

Application of a Ru film to capacitor electrodes of a dynamic random access memory, among various semiconductor memory devices, is explained using the schematic cross-section structure views of capacitor electrodes shown in FIGS. 10(a) to (c).

FIG. 10(a) shows the condition before the lower-layer electrode of a memory capacity is formed in the manufacturing process for dynamic random access memory cells having laminated capacitor electrodes. A silicon substrate 212 is in a so-called active range, being surrounded by an element separation range 213. Numeral 214 indicates a diffusion layer, and a conductive contact plug 216 is formed on the diffusion layer. Numeral 217 indicates a gate electrode, while numeral 219 indicates a conductive wire that becomes a bit wire. Numeral 218 is an inter-layer insulation film, numeral 221 is formed by the insulation film, and numeral 222 is a hole opening provided in a manner allowing a capacitor to be formed. A conductive layer connecting to the conductive plug is provided at the bottom of this hole opening 222. In FIG. 10(b), a Ru film 223 is formed inside this opening 222, and then a SrxTiyOz film 224 constituted by high-dielectric-constant Sr, Ti and oxygen is formed. Thereafter, a Ru film 225 is formed to form a capacitor structure sandwiched by Ru electrodes. Next, the surface is smoothened by means of CMP. In FIG. 10(c), a plate electrode 226 is formed on a Ru electrode 225 to provide electrical continuity to the Ru electrode 225. How to form the Ru films 223, 225 is explained below. After supplying a Ru material constituting a Ru precursor for 1 second using the sequence shown in FIG. 2(b), the Ru material is purged and then hydrogen radicals are supplied for 3 seconds from a radical source. As for the Ru material, a Ru precursor coordinated by β-diketones of the same structure, where X1 in FIG. 2(a) is expressed by 3H₃ and X2 is expressed by 3(CH₃), is supplied for 1 second. By repeating this cycle around 150 times, a Ru thickness of approx. 5 nm can be achieved.

TABLE 3

| | | Flow rate | Temperature | Pressure | Time |
|---|---|---|---|---|---|
| Step | Gas | (Sccm) | (° C.) | (Pa) | (sec) |
| Ru | Precursor | 300 | 280 | 300 | 1 |
| introduction | | | | | |
| Purge | Ar | 2000 | 280 | — | 1 |
| H radicals | H2/Ar | 300/2400 | 280 | 250 | 3 |
| Purge | Ar | 2000 | 280 | — | 1 |

Table 3 summarizes optimal conditions for this process. Formation of a Ru film using the apparatus illustrated in FIG. 3 is explained. The Ru precursor is controlled to an optimal vaporization temperature range of 80 to 150° C., or more preferable range of 100 to 120° C. Argon carrier gas is supplied at 300 sccm for 1 second from the valve 21. Next, the valve 21 is closed and a valve 22 is opened to introduce nitrogen gas or argon gas at a large flow rate, and the valve 9 is also opened roughly simultaneously to purge and exhaust the Ru material by means of an inert gas. Thereafter, the valves 22, 9 are closed and the valve 34 is opened. Mixture gas of hydrogen gas and argon gas is introduced from the valve 36. Once the pressure stabilizes at 250 Pa, the radical source 35 is started and hydrogen gas is converted to radicals, which are then supplied. After hydrogen radicals have been supplied for approx. 3 seconds, the radical source 35 is stopped and the valves 36, 34 are closed. Thereafter, evacuation is performed for approx. 1 second to complete one cycle. This cycle is set as desired in accordance with the target film thickness, to form a Ru film. Normally 0.2 to 0.4 angstrom of Ru film is formed in one cycle, which means that the process cycle needs to be repeated 100 to 500 times in order to form 5 to 10 nm of Ru. By using this method, a Ru film can be formed without oxidizing the surface of the conductive plug 216. Also, use of hydrogen in radical state has an advantage because normal parallel-plate hydrogen plasma has an extremely short life and therefore it is difficult to supply active hydrogen to the bottom of deep holes like those shown in FIG. 10 using parallel-plate plasma. Under a method conforming to an embodiment of the present invention, on the other hand, hydrogen is supplied as radicals and these hydrogen radicals are supplied to relatively deep holes, which improves coverage.

Accordingly, a Ru film offering favorable coverage can be formed, even over structures requiring high levels of coverage, by using a method conforming to an embodiment of the present invention.

### EXAMPLE 3

Application of a Ru film to semiconductor copper wiring using the process sequence in FIG. 2(a) is explained using the schematic cross-section structure view shown in FIG. 3.

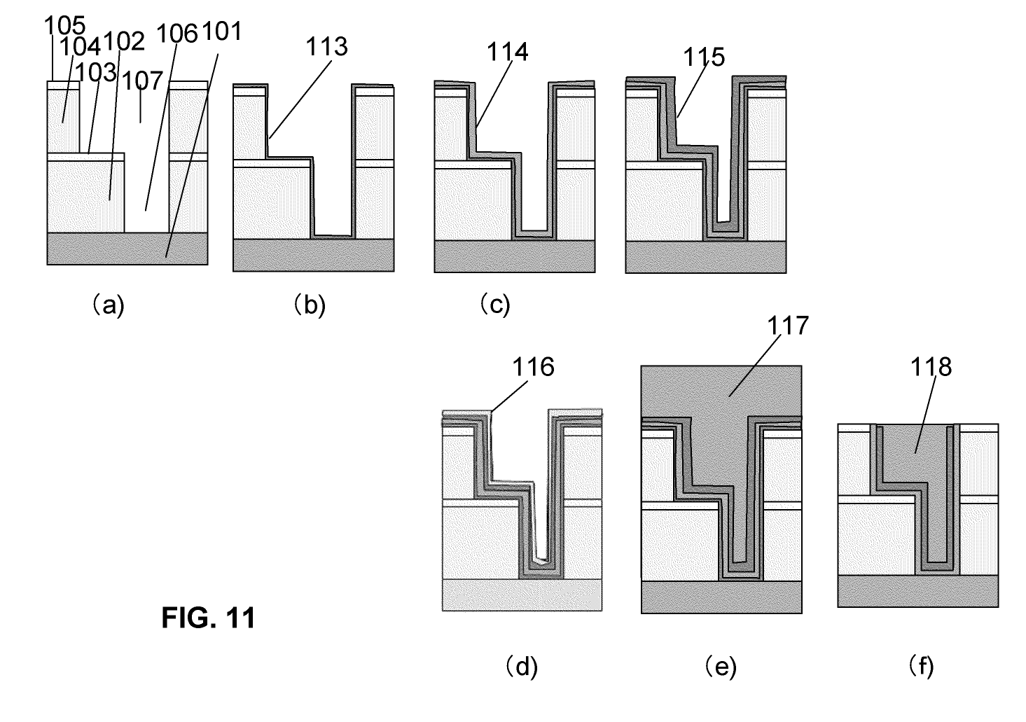

FIGS. 11(a) to (f) show a process for forming a Cu wiring by forming a Cu barrier film via dual damascene wiring and then forming a Cu seed layer, followed by Cu plating and Cu CMP. In FIG. 11(a), a via hole 106 is formed in an inter-layer insulation film 102 and a Cu barrier insulation film 103, and also a wiring trench 107 is formed in an inter-layer insulation film 104 and a Cu barrier insulation film 105, where all of the films are formed on a Cu lower-layer wiring 101. These via hole 106 and wiring trench 107 together constitute a Cu embedding range for dual damascene. In FIG. 11(b), a Ru film 113 is formed for 25 cycles, or approx. 1 nm, using a Ru forming method conforming to an embodiment of the present invention. The sequence in FIG. 2(a) is used to supply a Ru material constituting a Ru precursor for 1 second and then the Ru material is purged, after which hydrogen gas is supplied and high-frequency plasma is applied for approx. 2 seconds. By repeating this cycle 25 times, the Ru film thickness can be grown to approx. 1 mm. As for the Ru material, a Ru precursor coordinated by two types of β-diketone, one whose X1 and X2 in FIG. 2(b) are expressed by 3H₃ and the other whose X3 and X4 are expressed by 3(CH₃), was applied.

TABLE 4

| | | Flow rate | Temperature | Pressure | Time |
|---|---|---|---|---|---|
| Step | Gas | (Sccm) | (° C.) | (Pa) | (sec) |
| Ru | Precursor | 300 | 280 | 300 | 1 |
| introduction | | | | | |
| Purge | Ar | 2000 | 280 | — | 1 |
| Hydrogen | H2/Ar | 300/2400 | 280 | 250 | 3 |
| plasma | | | | | |
| Purge | Ar | 2000 | 280 | — | 1 |

Table 2 summarizes optimal conditions for this process. Formation of a Ru film using the apparatus illustrated in FIG. 3 is explained. The Ru precursor is controlled to an optimal vaporization temperature range of 80 to 150° C., and argon carrier gas is supplied at 300 sccm for 1 second from the valve 21. Next, the valve 21 is closed and a valve 22 is opened to introduce nitrogen gas or argon gas at a large flow rate, and the valve 9 is also opened roughly simultaneously to purge and exhaust the Ru material by means of an inert gas. Thereafter, the valves 22, 9 are closed and the valve 34 is opened. Mixture gas of hydrogen gas and argon gas is introduced from the valve 36. Once the pressure stabilizes at 250 Pa, high frequency is applied from the RF introduction terminal 33 to generate plasma. The high-frequency power supply uses 13.56 MHz and is adjusted using a matching box. In FIG. 3, the high-frequency power supply and matching box, which are connected to the RF introduction terminal 33, are not illustrated. Plasma is generated between the grounded substrate heating base 2 and showerhead 4, and after plasma has been supplied for approx. 3 seconds, high-frequency application is stopped and the valves 36, 34 are closed. Thereafter, evacuation is performed for approx. 1 second to complete one cycle. This cycle is set as desired in accordance with the target film thickness, to form a Ru film. Normally 0.2 to 0.4 angstrom of Ru film is formed in one cycle, which means that the process cycle needs to be repeated 25 to 50 times in order to form 1 nm of Ru. Next in FIG. 11(c), a TaNC film 114 is formed on this Ru film 113. Specifically, the TaNxCy film 114 is formed for 50 cycles, or approx. 3 nm, using the atomic layer deposition method using TAIMATA (Tertiaryamylimidotris(dimethylamido)tantalum) material and hydrogen plasma. Normally, x is adjusted to a range of 0.6 to 0.8, while y is adjusted to a range of 0.2 to 0.4. This forming method can be implemented under the conditions shown in Table 5.

TABLE 5

| | | Flow rate | Temperature | Pressure | Time |
|---|---|---|---|---|---|
| Step | Gas | (Sccm) | (° C.) | (Pa) | (sec) |
| Ta material | Taimata | 300 | 280 | 300 | 1 |
| introduction | | | | | |
| Purge | Ar | 2000 | 280 | — | 1 |
| Hydrogen | H2/Ar | 300/2400 | 280 | 250 | 3 |
| plasma | | | | | |
| Purge | Ar | 2000 | 280 | — | 1 |

Here, a sequence similar to the Ru forming sequence shown in FIG. 2(a) is used. The substrate heating temperature is set to 280° C., and TAIMATA is vaporized at 80° C., and then argon carrier gas is supplied at 300 sccm for 1 second. Thereafter, purge is performed and then hydrogen gas is supplied at 300 sccm, after which high frequency of 13.56 MHz is applied to perform hydrogen plasma treatment. Thereafter, purge is performed in a similar manner. By repeating this cycle 60 times, the thickness of TaNxCy film 114 can be increased to approx. 3 nm. In FIG. 11(c), a Ru film 115 is formed using a method conforming to an embodiment of the present invention on this TaNC film 114. The sequence in FIG. 2(a) is used to supply a Ru material constituting a Ru precursor for 1 second, after which the Ru material is purged, hydrogen gas is supplied, and high-frequency plasma is applied for approx. 3 seconds. By repeating this cycle around 25 to 100 times, the Ru film thickness can be grown to approx. 1 to 2 nm.

TABLE 6

| | | Flow rate | Temperature | Pressure | Time |
|---|---|---|---|---|---|
| Step | Gas | (Sccm) | (° C.) | (Pa) | (sec) |
| Ru | Precursor | 300 | 280 | 300 | 1 |
| introduction | | | | | |
| Purge | Ar | 2000 | 280 | — | 1 |
| Hydrogen | H2/Ar | 300/2400 | 280 | 250 | 3 |
| plasma | | | | | |
| Purge | Ar | 2000 | 280 | — | 1 |

Table 6 summarizes optimal conditions for this process. Formation of a Ru film using the apparatus illustrated in FIG. 3 is explained. The Ru precursor is controlled to an optimal vaporization temperature range of 80 to 150° C., and argon carrier gas is supplied at 300 sccm for 1 second from the valve 21. Next, the valve 21 is closed and a valve 22 is opened to introduce nitrogen gas or argon gas at a large flow rate, and the valve 9 is also opened roughly simultaneously to purge and exhaust the Ru material by means of an inert gas. Thereafter, the valves 22, 9 are closed and the valve 34 is opened. Mixture gas of hydrogen gas and argon gas is introduced from the valve 36. Once the pressure stabilizes at 250 Pa, high frequency is applied from the RF introduction terminal 33 to generate plasma. The high-frequency power supply uses 13.56 MHz and is adjusted using a matching box. In FIG. 3, the high-frequency power supply and matching box, which are connected to the RF introduction terminal 33, are not illustrated. Plasma is generated between the grounded substrate heating base 2 and showerhead 4, and after plasma has been supplied for approx. 3 seconds, high-frequency application is stopped and the valves 36, 34 are closed. Thereafter, evacuation is performed for approx. 1 second to complete one cycle. This cycle is set as desired in accordance with the target film thickness, to form a Ru film. Normally 0.2 to 0.4 angstrom of Ru film is formed in one cycle, which means that the process cycle needs to be repeated 25 to 100 times in order to form 1 to 2 nm of Ru. In FIG. 11(d), a 5-nm Cu film 116 is formed by the CVD method, where the Cu-CVD film 116 uses Cu(Hfac)2tmvs. Here, any known Cu-CVD technology can be used to form this Cu-CVD film on a Ru film 115 conforming to an embodiment of the present invention. In FIG. 11(e), a Cu plating film 117 is formed on the Cu-CVD film 116. In FIG. 11(f), this Cu plating film 117 can be polished by means of Cu-CMP to form a Cu wiring 118. Here, the crystalline property of the 5-nm Ru film exhibits (002)-preferred orientation in the same manner as shown in FIG. 5. This suggests that an extremely smooth 5-nm Cu film can be formed on Ru. Accordingly, this structure can be used to easily form a smooth Cu seed film of 5 nm or less. It is also possible to achieve similar effects using a PVD-Cu film, instead of a CVD-Cu film, because PVD-Cu also exhibits favorable adhesion on a Ru film conforming to an embodiment of the present invention.

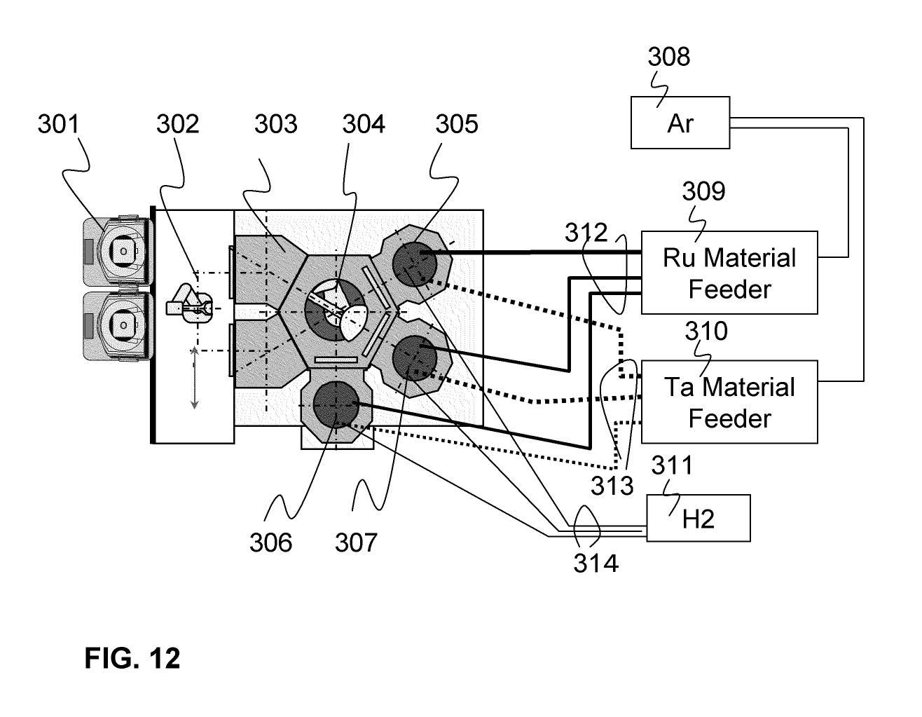

As shown in this example, the Ru film 113, TaNC film 114 and Ru film 115 are formed at the same temperature, and accordingly they could be formed successively in vacuum inside the same reactor shown in FIG. 12. FIG. 12 shows a cluster apparatus having multiple reaction chambers, comprising cassette loaders 301, an atmospheric transfer robot chamber 302, road lock chambers 303 and a vacuum transfer robot chamber 304. Numerals 305, 306 and 307 are all identical reaction chambers, and Ru and TaNC films can be formed in each of these reaction chambers. Numeral 308 indicates an Ar gas supply part used to supply Ru and Ta materials. Numerals 309, 310 and 311 indicate a Ru material supply part, Ta material supply part and H₂ gas supply part, respectively, where pipes 312, 313, 314 are used to supply each material/gas to the reaction chambers 305, 306, 307. Accordingly, the reaction chambers 305, 306, 307 can perform the Ru or TaNC film forming process simultaneously. This reduces the time needed to transfer wafers, etc., and consequently improves the productivity. As a result, the cluster apparatus shown in FIG. 12 can form multiple Ru/TaNC/Ru laminated films or TaNC/Ru laminated films simultaneously at a favorable productivity level. Furthermore, a process where Ru and TaNC are combined by a desired number of times can also be performed with ease.

As explained above, a wiring exhibiting extremely favorable adhesion can be formed using a Ru film conforming to an embodiment of the present invention, and a Cu/Ru/TNC structure containing such Ru film. Also, the underlying TaNC layer is not nitrided and can be formed continuously with ease, which provides the effect of improving productivity compared when a conventional Ru film is used. In the aforementioned applications, you can substitute the TaNC film by a Ru-containing metal film such as RuTa, RuTaNC, RuTaN, RuTi, RuTiNC or RuTiN film, and still achieve similar effects. In particular, adhesion with the Ru film increases further by adding Ru to the lower layer.

The present invention includes the above mentioned embodiments and other various embodiments including the following:

1) A method for depositing a thin ruthenium (Ru) film on a substrate in a reaction chamber, comprising: step (i) of supplying at least one type of gas of a ruthenium precursor being a β-diketone-coordinated ruthenium complex and causing the gas to be adsorbed to the substrate in the reaction chamber; step (ii) of supplying a reducing gas into the reaction chamber and exciting the reducing gas, or supplying an excited reducing gas into the reaction chamber, thereby activating the ruthenium precursor adsorbed to the substrate; and step (iii) of repeating steps (i) and (ii) to form a thin ruthenium film on the substrate.

2) A method according to 1), wherein the ruthenium complex has a Ru(X)n structure (X is a β-diketone ligand, while n is 2 or 3), or more preferably a Xa-Ru-Xb or Xa-Ru-Xa structure where Xa and Xb represent different β-diketone ligands.

3) A method according to 2), characterized in that the β-diketone group expressed by Xa is a 2,4-pentenedione group where at least one of carbon 1 and carbon 5 is bonded to an alkyl group.

4) A method according to 2), characterized in that the β-diketone group expressed by Xb is a 2,4-pentenedione group where at least one of carbon 1 and carbon 5 is bonded to an alkyl group.

5) A method according to 3), wherein the β-diketone group expressed by Xa is an acetyl acetone group, dipivaloyl methane group, diisobutyryl methane group or isopivaloyl methane group.

6) A method according to 4), wherein the β-diketone group expressed by Xb is an acetyl acetone group, dipivaloyl methane group, diisobutyryl methane group or isopivaloyl methane group.

7) A method according to 1), wherein the gas supplied in step (ii) is a reducing gas and this reducing gas is at least one of hydrogen, gas containing hydrogen, or gas constituted by hydrogen atoms.

8) A method according to 1), wherein the gas supplied in step (ii) is an excited reducing gas and this step includes a step of generating a reducing gas that has been excited by applying high-frequency power to the reducing gas upstream of the reaction chamber.

9) A method according to 1), further comprising a step of purging the ruthenium precursor from the reaction chamber after step (i) and a step of purging the excited reducing gas from the reaction chamber after step (ii).

10) A method according to 1), wherein steps (i) and (ii) are repeated until the thickness of the formed thin ruthenium film becomes 0.5 nm or more, but not exceeding 2.0 nm.

11) A method according to 1), wherein steps (i) and (ii) are repeated until the preferred crystalline orientation of the formed thin ruthenium film becomes Ru (002).

12) A method according to 1), wherein steps (i) and (ii) are repeated until the thickness of the formed thin ruthenium film becomes 0.5 nm or more, but not exceeding 2.0 nm and also until the preferred crystalline orientation of the ruthenium film becomes Ru (002).

13) A method according to any one of 1) to 12), further comprising a step to form a metal film on the substrate before the start of steps (i) to (iii) for forming a thin ruthenium film.

14) A method according to 13), wherein the metal film is at least one type selected from the group that includes WNxCy, WN, TaN, Ta, TaNxCy, TiN and Ti.

15) A method according to 1), wherein the gas of the ruthenium precursor in step (i) is used as a first gas, while a further step is included in step (i) to supply a second gas of a different ruthenium precursor into the reaction chamber simultaneously as the first gas.

16) A method according to 1), further comprising after step (iii): step (iv) of supplying gas of a ruthenium precursor into the reaction chamber and causing the gas to be adsorbed to the substrate; step (v) of supplying into the reaction chamber an oxidizing gas or molecules constituted by oxygen atoms so as to activate the ruthenium precursor adsorbed to the substrate; and step (vi) of repeating steps (iv) and (v) and thereby forming a thin ruthenium film or thin ruthenium oxide film on the thin ruthenium film formed in step (iii).

17) A method according to 1), further comprising after step (iii): step (iv) of supplying into the reaction chamber a second gas of a different ruthenium precursor and causing the second gas of the different ruthenium precursor to be adsorbed to the substrate; step (v) of supplying a reactant gas to activate the second gas of the different ruthenium precursor adsorbed to the substrate; and step (vi) of repeating steps (iv) and (v) and thereby forming a thin ruthenium film or thin ruthenium oxide film on the thin ruthenium film formed in step (iii).

18) A method according to any one of 1) to 12), further comprising a step of forming on the thin ruthenium film after step (iii) a thin ruthenium film or thin ruthenium oxide film by means of CVD.

19) A method according to any one of 1) to 12), further comprising a step of forming a copper film on the thin ruthenium film after step (iii).

20) A method according to any one of 16) to 18), further comprising a step of forming a copper film on the thin ruthenium film or thin ruthenium oxide film formed in the step following step (iii).

21) A method according to 11), further comprising a step of forming a copper film on the thin ruthenium film having (002)-preferred crystal orientation after step (iii).

22) A method according to 12), further comprising a step of forming a copper film on the thin ruthenium film having a thickness of 0.5 nm or more, but not exceeding 2.0 μm as well as (002)-preferred crystal orientation after step (iii).

23) A method according to any one of 15) to 22), further comprising a step of adding a metal film on the substrate before the start of steps (i) to (iii) for forming a thin ruthenium film, and a step of forming a copper film on the thin ruthenium film after steps (i) to (iii).

24) A method according to 23), wherein the metal film is at least one type selected from the group that includes WNxCy, WN, TaN, Ta, TaNxCy, TiN and Ti.

25) A method according to any one of 19) to 24), wherein the copper film is formed by supplying onto the substrate a copper precursor gas generated by means of CVD or ALD.

26) A thin ruthenium film formation structure, comprising a substrate and a thin ruthenium film formed on the substrate by any one of the methods according to 1) to 25).

27) A thin ruthenium film formation structure according to 26), wherein the thin ruthenium film has (002)-preferred crystal orientation.

28) A thin ruthenium film formation structure according to 26) or 27), wherein the thin ruthenium film has a thickness of 0.5 μm or more, but not exceeding 2.0 nm.

29) A thin ruthenium film formation structure according to 26), 27) or 28), wherein the substrate has a metal film and the thin ruthenium film is formed on the metal film.

30) A thin ruthenium film formation structure according to 29), wherein the metal film is at least one type selected from the group that includes WNC, WN, TaN, Ta, TaNC, TiN, Ti, Cu, Al, Co and Ni.

31) A thin ruthenium film formation structure according to 26), 27) or 28), wherein the thin ruthenium film has on its top at least one type of metal film selected from the group that includes WNC, WN, TaN, Ta, TaNC, TiN and Ti and Cu is formed on top of this metal film.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A method for depositing a thin ruthenium (Ru) film on a substrate in a reaction chamber, comprising:
step (i) of supplying at least one type of gas of a ruthenium precursor being a β-diketone-coordinated ruthenium complex and causing the gas to be adsorbed to the substrate in the reaction chamber;
step (ii) of supplying a reducing gas into the reaction chamber and exciting the reducing gas, or supplying an excited reducing gas into the reaction chamber, thereby activating the ruthenium precursor adsorbed to the substrate; and
step (iii) of repeating steps (i) and (ii) to form a thin ruthenium film on the substrate.

2. The method according to claim 1, wherein the ruthenium complex has a Ru(X)n structure (X is a β-diketone ligand, while n is 2 or 3).

3. The method according to claim 2, wherein the β-diketone group expressed by Xa is a 2,4-pentenedione group where at least one of carbon 1 and carbon 5 is bonded to an alkyl group.

4. The method according to claim 2, wherein the β-diketone group expressed by Xb is a 2,4-pentenedione group where at least one of carbon 1 and carbon 5 is bonded to an alkyl group.

5. The method according to claim 3, wherein the β-diketone group expressed by Xa is an acetyl acetone group, dipivaloyl methane group, diisobutyryl methane group or isopivaloyl methane group.

6. The method according to claim 4, wherein the β-diketone group expressed by Xb is an acetyl acetone group, dipivaloyl methane group, diisobutyryl methane group or isopivaloyl methane group.

7. The method according to claim 1, wherein the gas supplied in step (ii) is a reducing gas and this reducing gas is at least one of hydrogen, mixture gas of hydrogen and nitrogen, or gas constituted by hydrogen atoms.

8. The method according to claim 1, wherein the gas supplied in step (ii) is an excited reducing gas and this step includes a step to generate a reducing gas that has been excited by applying high-frequency power to the reducing gas upstream of the reaction chamber.

9. The method according to claim 1, further comprising a step of purging the ruthenium precursor from the reaction chamber after step (i) and a step of purging the excited reducing gas from the reaction chamber after step (ii).

10. The method according to claim 1, wherein steps (i) and (ii) are repeated until the thickness of the formed thin ruthenium film becomes 0.5 nm or more, but not exceeding 2.0 nm.

11. The method according to claim 1, wherein steps (i) and (ii) are repeated until the preferred crystalline orientation of the formed thin ruthenium film becomes Ru (002).

12. The method according to claim 1, wherein steps (i) and (ii) are repeated until the thickness of the formed thin ruthenium film becomes 0.5 nm or more, but not exceeding 2.0 nm and also until the preferred crystalline orientation of the ruthenium film becomes Ru (002).

13. The method according to any one of claim 1, further comprising a step of forming a metal film on the substrate before the start of steps (i) to (iii) for forming a thin ruthenium film.

14. The method according to claim 13, wherein the metal film is at least one type selected from the group consisting of WNxCy, WN, TaN, RuTaN, Ta, RuTa, TaNxCy, RuTaNxCy, TiN, RuTiN, Ti, and RuTi.

15. The method according to claim 1, further comprising after step (iii):
step (iv) of supplying gas of a ruthenium precursor into the reaction chamber and causing the gas to be adsorbed to the substrate;
step (v) of supplying into the reaction chamber an oxidizing gas or molecules constituted by oxygen atoms so as to activate the ruthenium precursor adsorbed to the substrate; and
step (vi) of repeating steps (iv) and (v) and thereby forming a thin ruthenium film or thin ruthenium oxide film on the thin ruthenium film formed in step (iii).

16. The method according to claim 1, further comprising a step of forming a copper film on the thin ruthenium film after step (iii).

17. The method according to claim 15, further comprising a step of forming a copper film on the thin ruthenium film or thin ruthenium oxide film formed in the step following step (iii).

18. The method according to claim 11, further comprising, after step (iii), a step of forming a copper film on the thin ruthenium film having (002)-preferred crystal orientation.

19. The method according to claim 12, further comprising, after step (iii), a step of forming a copper film on the thin ruthenium film having a thickness of 0.5 nm or more, but not exceeding 2.0 nm, and (002)-preferred crystalline orientation.

20. A thin ruthenium film formation structure, comprising:
a substrate, and
a thin ruthenium film formed on the substrate by the atomic layer deposition method and having (002)-preferred crystalline orientation.

21. The method according to claim 2, wherein the Ru(X)n structure has a Xa-Ru-Xb or Xa-Ru-Xa structure where Xa and Xb represent different β-diketone ligands.
